(19) United States
(12) Patent Application Publication
(10) Pub. No.: US 2004/0259371 A1
(43) Pub. Date: Dec. 23, 2004

(54) Reduction of resist defects

(76) Inventor: Zhijian Lu, Plano, TX (US)

Correspondence Address: SLATER & MATSIL, L.L.P., 17950 PRESTON RD, SUITE 1000, DALLAS, TX, 75252-5793, US

(21) Appl. No.: 10/464,193

(22) Filed: Jun. 18, 2003

(51) Int. Cl. H01L 21/302

(52) U.S. Cl. 438/745

(57) ABSTRACT

Photoresist patterning defects, such as “kissing” defects, can be reduced by rinsing semiconductor wafers in a surfactant-containing rinse, instead of deionized water, at the end of the development process.

### FIELD OF THE INVENTION

The invention relates generally to semiconductor manufacturing, and, more particularly, to reducing resist defects.

### BACKGROUND OF THE INVENTION

Since the beginning of semiconductor manufacturing, photolithography has been recognized as a driving force behind the integrated circuit (“IC”) fabrication process. Photolithography enables the industry to pack more devices and associated circuitry on each chip. The essence of photolithography is the imprinting of temporary circuit structures on a wafer. These circuit structures can then be used to assist etch and ion implant processes. Photolithography produces a three-dimensional pattern on the surface of the wafer using a light-sensitive photoresist material and controlled exposure to light.

There are eight (8) basic steps in a conventional photolithography process: vapor prime, spin coat, soft bake, alignment and exposure, post-exposure bake (“PEB”), development, hard bake, and development inspection. Development is the critical step for creating the pattern in the photoresist on the wafer surface. The soluble areas of the photoresist are dissolved by liquid developer chemicals, leaving visible patterns of islands and windows on the wafer surface. The primary goal of photoresist development is to accurately replicate the reticle pattern in the resist material while maintaining acceptable resist adhesion. The emphasis is on producing critical dimension (“CD”) features that meet the required specifications. If the CDs meet the specifications, then all other features are assumed to be acceptable since the CD is the most difficult structure to develop. Some common methods for development are spin, spray, and puddle. Conventionally, as a final step in the development process, the wafers are rinsed in deionized (“DI”) water and then spin-dried.

Resist patterning problems can occur if the development process is not properly controlled. These resist problems can negatively affect production yield, showing up as defects in the subsequent etch process. One such defect is commonly known as a “kissing” defect. Kissing defects are undissolved resist residues that connect resist lines, causing electrical shorts or opens. FIG. 1 diagrammatically illustrates kissing defects 120 resulting from a conventional resist development process. In FIG. 1, kissing defects 120 connect resist lines 110.

It is therefore desirable to provide a solution that reduces resist defects. The present invention provides this in some embodiments by completing the resist development process with a surfactant-containing rinse instead of DI water.

### BRIEF DESCRIPTION OF THE DRAWINGS

The above and further advantages of the invention may be better understood by referring to the following description in conjunction with the accompanying drawings in which corresponding numerals in the different figures refer to the corresponding parts, in which:

FIG. 1 diagrammatically illustrates exemplary embodiments of resist patterning defects in accordance with the known art;

FIG. 2 illustrates a conventional resist development process in accordance with the known art;

FIG. 3 illustrates exemplary embodiments of a resist development process in accordance with the present invention; and

FIG. 4 diagrammatically illustrates resist patterning as a result of the use of exemplary embodiments of the present invention.

### DETAILED DESCRIPTION

While the making and using of various embodiments of the present invention are discussed herein in terms of specific resist defects, it should be appreciated that the present invention provides many inventive concepts that can be embodied in a wide variety of contexts. The specific embodiments discussed herein are merely illustrative of specific ways to make and use the invention, and are not meant to limit the scope of the invention.

The present invention provides a solution that reduces resist defects. The present invention provides this by completing the conventional resist development process with a surfactant-containing rinse instead of DI water.

There are several critical parameters that must be controlled during a conventional resist development process. These parameters are: developer temperature, developer time, developer volume, wafer chuck, normality, rinse, and exhaust flow. A conventional resist development process is illustrated in FIG. 2. In block 205, a developer is applied to a wafer. Next, in block 210, the developer is then allowed time to dissolve soluble resist areas. The wafer is then rinsed (block 215) which serves to stop the development process and remove developer from the wafer surface. Conventionally, as shown in block 215, deionized (“DI”) water is used as a rinsing agent. Then, in block 220, the wafer is dried.

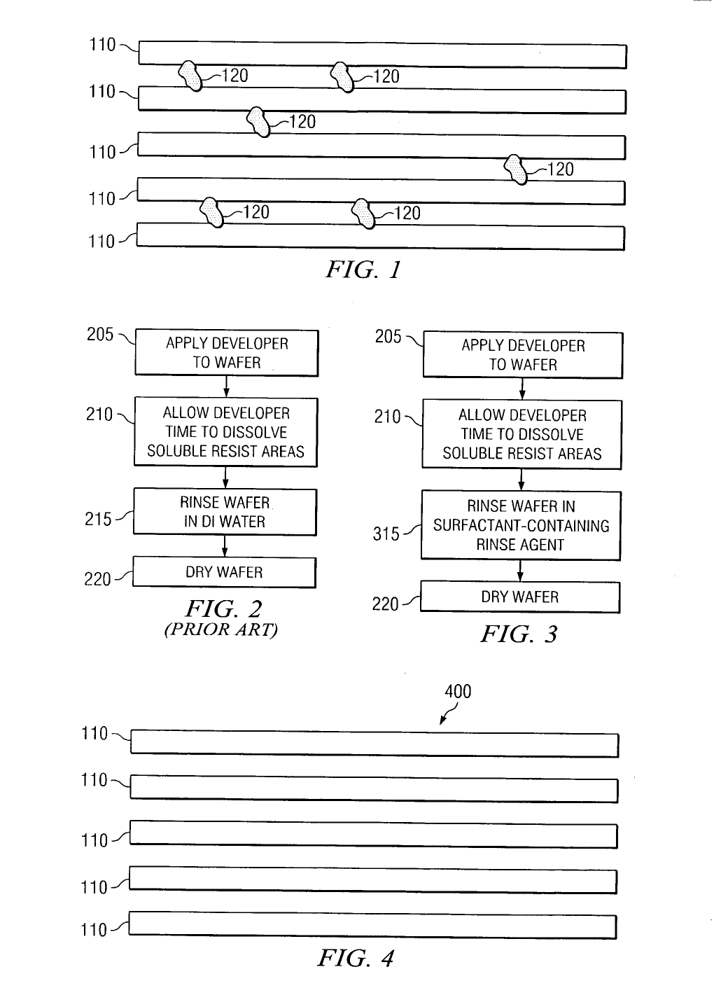

In accordance with exemplary embodiments of the present invention, a surfactant-containing rinse agent can replace the DI water in the conventional resist development process of FIG. 2, as shown in block 315 of FIG. 3. A surfactant-containing rinse agent can reduce resist defects related to low solubility of resist polymers. Surfactants have a higher dissolution rate than DI water, thereby enabling the removal of polymer residues that form the defects. Additionally, surfactants can form a hydrophilic layer over the resist that can minimize the possibility of redeposition of resist residues. In some exemplary embodiments, the rinse agent can be a water rinse including an ammonium Lauryl sulfate (“ALS”) content ranging from approximately 0.005% to approximately 5%, for example, approximately 0.05%. FIG. 4 diagrammatically illustrates resist patterning 400 as a result of the use of exemplary embodiments of the present invention. Kissing defects 120 that remained in FIG. 1 can be dissolved through the use of a surfactant-containing rinse agent (FIG. 3, block 315), leaving clean resist lines 110, as shown in FIG. 4.

Although exemplary embodiments of the present invention have been described in detail, it will be understood by those skilled in the art that various modifications can be made therein without departing from the spirit and scope of the invention as set forth in the appended claims.

What is claimed is:

1. A method for developing a photoresist material on a semiconductor wafer, the method comprising:
dissolving a soluble area of the photoresist material in a developer; and
thereafter rinsing the wafer in a surfactant-containing rinse agent.

2. The method of claim 1, wherein the surfactant-containing rinse agent includes ammonium Lauryl sulfate.

3. The method of claim 2, wherein the rinse agent is 0.005% to 5% ammonium Lauryl sulfate.

4. The method of claim 1, wherein the rinse agent is an approximately 0.05% ammonium Lauryl sulfate water rinse.

5. The method of claim 1, wherein the photoresist material is a positive photoresist material.

6. The method of claim 1, wherein the photoresist material is a negative photoresist material.

7. The method of claim 1, wherein the rinsing step includes dissolving additional photoresist material.

8. A method for developing a photoresist material on a semiconductor wafer, the method comprising:
dissolving a soluble area of the photoresist material in a developer;
thereafter applying to the wafer a rinse agent, including the rinse agent dissolving additional photoresist material; and
after said last-mentioned dissolving step, drying the rinse agent from the wafer.

9. The method of claim 8, wherein the rinse agent includes a surfactant.

10. The method of claim 8, wherein the rinse agent includes ammonium Lauryl sulfate.

11. The method of claim 10, wherein the rinse agent is 0.005% to 5% ammonium Lauryl sulfate.

12. The method of claim 8, wherein the rinse agent is an approximately 0.05% ammonium Lauryl sulfate water rinse.

13. The method of claim 8, wherein the photoresist material is a positive photoresist material.

14. The method of claim 8, wherein the photoresist material is a negative photoresist material.

15. An article of manufacture, comprising a semiconductor wafer and a layer of photoresist material coated on said semiconductor wafer, and having therein a pattern created by developing the photoresist material according to the method of claim 8.

16. A semiconductor apparatus, comprising:
a semiconductor wafer;
a photoresist material coated on said semiconductor wafer; and
said photoresist material having defined therein a pattern created by dissolving a soluble area of the photoresist material in a developer and then rinsing the semiconductor wafer in a surfactant-containing rinse agent.

17. The apparatus of claim 16, wherein the surfactant-containing rinse agent includes ammonium Lauryl sulfate.

18. The apparatus of claim 17, wherein the rinse agent is 0.005% to 5% ammonium Lauryl sulfate.

19. The apparatus of claim 16, wherein the rinse agent is an approximately 0.05% ammonium Lauryl sulfate water rinse.

20. The apparatus of claim 16, wherein the photoresist material is one of a positive photoresist material and a negative photoresist material.
